(19) United States
(12) Patent Application Publication
(10) Pub. No.: US 2026/0202479 A1
(43) Pub. Date: Jul. 16, 2026

(54) METHOD FOR CORRECTING BATTERY MEASUREMENT INFORMATION AND DEVICE THEREFOR

(71) Applicant: MONA INC., Jeollabuk-do (KR)

(72) Inventor: Chang Hee SONG, Seoul (KR)

(73) Assignee: MONA INC., Jeollabuk-do (KR)

(21) Appl. No.: 19/113,915

(22) PCT Filed: Sep. 14, 2023
(86) PCT No.: PCT/KR2023/013850

§ 371 Date: Mar. 21, 2025

(30) Foreign Application Priority Data
Sep. 21, 2022 (KR) 10-2022-0119514

(51) Int. Cl. G01R 31/374; G01R 31/389; G01R 31/396

(52) U.S. Cl. CPC G01R 31/374; G01R 31/389; G01R 31/396

(57) ABSTRACT

Disclosed are a method for correcting battery measurement information and a device therefor. The battery measurement information correction device sets an alternating-current resistance of a battery sample measured by measuring equipment at a first time point as a reference alternating-current resistance, determines a first deviation between an alternating-current resistance obtained by measuring the battery sample by using the measuring equipment at a second time point and the reference alternating-current resistance, and corrects an alternating-current resistance of a battery cell measured by the measuring equipment at the second time point by using the first deviation. The present disclosure was supported by the Ministry of SMEs and Startups' green venture program project (Task No. S3212046, Task Unique No. 1425175618) and Ministry of Trade, Industry and Energy's automobile industry technology development project (Task No. 20021923, Task Unique No. 1415181483).

### TECHNICAL FIELD

An embodiment of the present disclosure relates to a method of correcting battery measurement information and a device therefor, and more specifically, to a method of correcting a deviation between pieces of battery measurement information measured under different environmental conditions, and a device therefor.

The present disclosure was supported by the Green Venture Program Project of the Ministry of SMEs and Startups (Project No.: S3212046, Project Unique Number: 1425175618) and the Automobile Industry Technology Development Project of the Ministry of Trade, Industry and Energy (Project No.: 20021923, Project Unique Number: 1415181483).

### BACKGROUND ART

Batteries are being utilized in various fields such as electric vehicles and energy storage systems (ESSs). Batteries that may be recharged and used (e.g., secondary batteries) deteriorate due to various factors such as a period of use or an environment in which they are used, and therefore, it is necessary to determine a battery status in order to determine a timing of battery replacement. In order to determine the battery status, various values such as a voltage, resistance, and remaining charge of the battery may be measured using measuring equipment. However, even if the same measuring equipment is used, battery measurement results may differ each time due to environmental factors such as a surrounding temperature or humidity at the time of measurement.

### DISCLOSURE OF INVENTION

### Technical Problem

The technical problem to be solved by an embodiment of the present disclosure is to provide a method and device for correcting deviation of battery measurement information due to environmental factors.

### Solution to Problem

An embodiment of the present disclosure provides a method of correcting battery measurement information, the method including setting an alternating-current resistance of a battery sample measured by using measuring equipment at a first time point as a reference alternating-current resistance, determining a first deviation between an alternating-current resistance obtained by measuring the battery sample by using the measuring equipment at a second time point and the reference alternating-current resistance, and correcting an alternating-current resistance of a battery cell measured by the measuring equipment at the second time point by using the first deviation.

An embodiment of the present disclosure provides a battery measurement information correction device including a reference setting unit that sets an alternating-current resistance of a battery sample measured by measuring equipment at a first time point as a reference alternating-current resistance, a deviation detection unit that detects a first deviation between an alternating-current resistance obtained by measuring the battery sample by using the measuring equipment at a second time point and the reference alternating-current resistance, and a correction unit that corrects an alternating-current resistance of a battery cell measured by the measuring equipment at the second time point by using the first deviation.

### Advantageous Effects of Invention

According to an embodiment of the present disclosure, deviations caused by environmental factors such as temperature or humidity at the time of battery measurement may be corrected. Because measurement information is stored by correcting deviations caused by environmental factors, the measurement information may be utilized as big data or training data for artificial intelligence models.

### BRIEF DESCRIPTION OF DRAWINGS

FIG. 1 is a diagram illustrating an example of a battery measurement information correction device according to an embodiment of the present disclosure,

FIG. 2 is a diagram illustrating an example of a deviation of alternating-current resistance by measuring equipment according to an embodiment of the present disclosure,

FIG. 3 is a diagram illustrating an example of a method of correcting a measurement equipment-specific deviation according to an embodiment of the present disclosure,

FIG. 4 is a diagram illustrating an example of a method of correcting a deviation of measuring equipment by period according to an embodiment of the present disclosure,

FIG. 5 is a diagram illustrating an example of a user interface for correcting a deviation of battery measurement information according to an embodiment of the present disclosure,

FIG. 6 is a flowchart illustrating an example of a battery measurement information correction method according to an embodiment of the present disclosure, and

FIG. 7 is a diagram illustrating a configuration of an example of a battery measurement information correction device according to an embodiment of the present disclosure.

### MODE FOR THE INVENTION

Hereinafter, with reference to the attached drawings, a method of correcting battery measurement information and a device therefor according to an embodiment of the present disclosure will be described in detail.

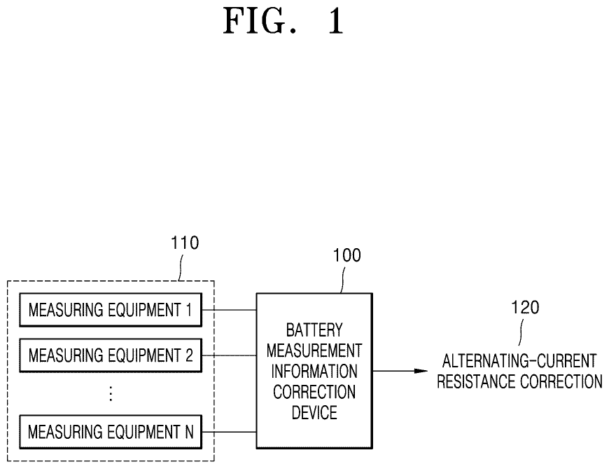

FIG. 1 is a diagram illustrating an example of a battery measurement information correction device 100 according to an embodiment of the present disclosure.

Referring to FIG. 1, the battery measurement information correction device 100 (hereinafter referred to as a ‘correction device’) receives battery measurement information measured using measuring equipment 110 under different environmental conditions. The measuring equipment 110 is a device that may measure various values such as voltage, current, and resistance of a battery, and various conventional measuring equipment may be applied to the present embodiment. In an embodiment, the battery measured by the measuring equipment 110 may be a battery cell.

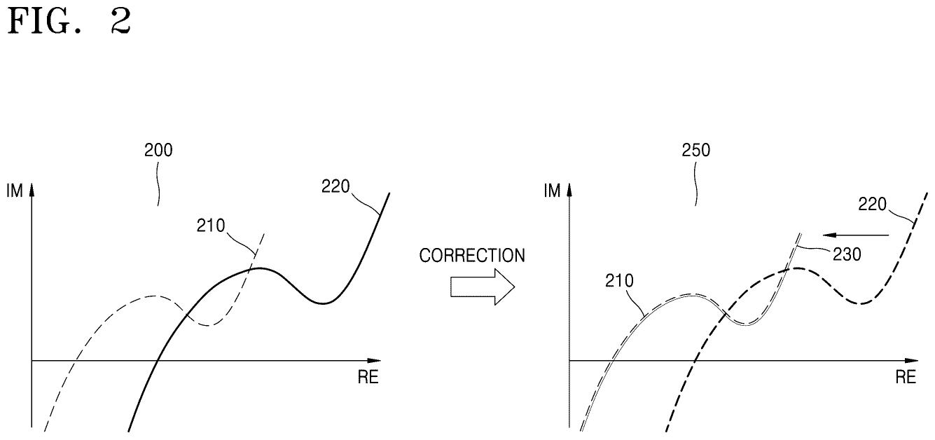

If the measuring equipment 110 measures the same battery under different environmental conditions (e.g., temperature, humidity, etc.), the measurement information may be different as shown in FIG. 2. Depending on the time or place of measuring a battery, environmental conditions such as temperature and humidity may vary, and thus, measurement information (e.g., voltage, current, resistance, etc.) may also vary. For example, as shown in FIG. 2, an alternating-current resistance measured by applying an alternating-current voltage to the battery may vary depending on the environmental conditions. In addition, deviations between various measurement information may occur depending on the environmental conditions. However, for the convenience of explanation, the following description assumes that the correction device 100 performs correction 120 on an alternating-current resistance of a battery measured using the measuring equipment 110 under different environmental conditions.

FIG. 2 is a diagram illustrating an example of deviations in alternating-current resistance by measuring equipment according to an embodiment of the present disclosure.

Referring to FIG. 2, a graph in which values of alternating-current resistances of a same battery measured by frequency by using same measuring equipment under different environmental conditions are connected and shown on a complex plane is illustrated. For example, the alternating-current resistance by frequency of the battery may be measured by applying the frequency of an alternating-current voltage to the battery while changing the frequency at regular interval in a certain frequency band. Various conventional methods for measuring the alternating-current resistance may be applied to the present embodiment.

The left graph 200 is a graph before the alternating-current resistance correction, and the right graph 250 is a graph after the correction. Even though the alternating-current resistance of the same battery was measured with the same measuring equipment under first and second environmental conditions, the overall shape is similar, but there is a deviation between the alternating-current resistances by frequency. Therefore, a process of correcting the deviation (i.e., moving from 220=>230) is necessary so that the alternating-current resistance 220 measured under the second environmental condition matches the alternating-current resistance 210 measured under the first environmental condition.

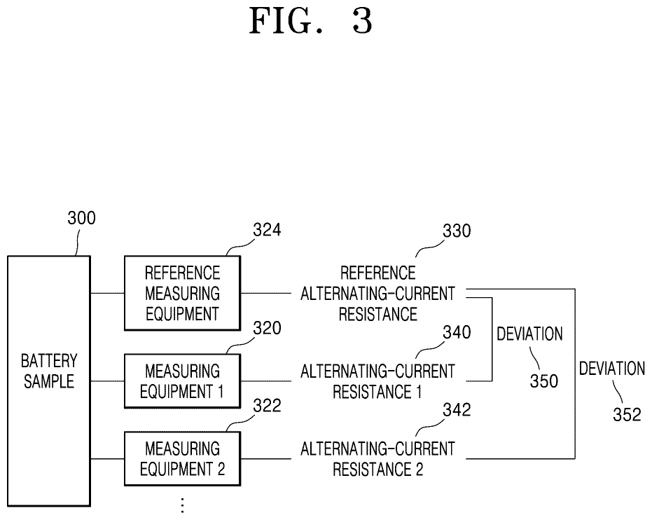

In the case of using the alternating-current resistance of a battery in big data or an artificial intelligence model, the deviation between the measurement information according to the environmental conditions results in lowering the performance of big data analysis or artificial intelligence model training. The alternating-current resistance obtained by measuring the same battery cell needs to always be constant regardless of the environmental conditions to improve the results of analysis, training, etc. Accordingly, the correction device 100 performs a process of correcting the deviation of the alternating-current resistance using the method described with reference to FIG. 3 and below.

FIG. 3 is a diagram illustrating an example of a method of correcting a measurement equipment-specific deviation according to an embodiment of the present disclosure.

Referring to FIG. 3, the alternating-current resistance of a battery cell 300 is measured using the same measuring equipment 324, 320, 322 at multiple time points 310, 312, and 314. The environmental conditions such as temperature and humidity may be different at each of the multiple time points 310, 312, and 314. A battery cell measured to correct a deviation between multiple time points 310, 312, and 314 is referred to as a ‘battery sample’ 300 hereinafter. In an embodiment, the battery sample 300 may include multiple battery cells. The battery sample 300 is a battery cell set in advance to determine a deviation.

The alternating-current resistance of the battery sample 300 measured by measuring equipment at the first time point 310 is set as a reference alternating-current resistance 330. For example, when the battery sample 300 includes multiple battery cells, the measuring equipment measures the alternating-current resistance of each of the multiple battery cells. In addition, the correction device 100 may set the reference alternating-current resistance 330 by adding up the multiple alternating-current resistances measured at the first time point 310 by using a statistical method such as an average. For example, the correction device 100 may obtain an average of multiple alternating-current resistances by using an average value (Equation 1), an intermediate value (Equation 2), or an average value using an ignition formula (Equation 3). This may be expressed Equations as follows:

$$\overline{X} = \frac{1}{N} {\sum }_{i}^{N} {x}_{i} \qquad [ Equation 1 ]$$

$$\text{?} \qquad [ Equation 2 ]$$

$${\overline{X}}_{N} = \frac{{x}_{1} + {x}_{2} + … + {x}_{N}}{N} \qquad [ Equation 3 ]$$

$${\overline{X}}_{N - 1} = \frac{{x}_{1} + {x}_{2} + … + {x}_{N - 1}}{N - 1}$$

$$\frac{N}{N - 1} {\overline{X}}_{N} = \frac{{x}_{1} + {x}_{2} + … + {x}_{N}}{N - 1} = {\overline{X}}_{N - 1} + \frac{xN}{N - 1}$$

$$∴ {\overline{X}}_{N} = \frac{N - 1}{N} {\overline{X}}_{N - 1} + \frac{1}{N} {x}_{N}$$

Here, xi represents the alternating-current resistance of each battery cell, and N represents the number of battery cells. In the case of Equation 3, because the average value is updated whenever a new value is input, there is an advantage of a small amount of computation in actual application.

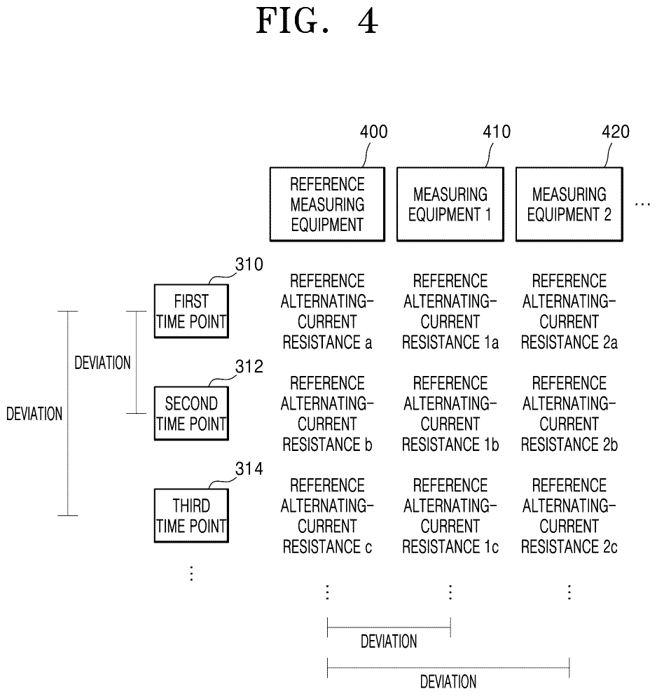

The correction device 100 receives measured values of the alternating-current resistances 340 and 342 of the battery sample 300 from the measuring equipment at second and third time points 312 and 314 (see FIG. 4) of n (n is a natural number greater than or equal to 2). If the battery sample 300 includes multiple battery cells, the measuring equipment measures the alternating-current resistance of the multiple battery cells at each of the second and third time points 312 and 314. The correction device 100 may obtain alternating-current resistances 340 and 342 at each of the second and third time points 312 and 314 by statistically adding the alternating-current resistances of multiple battery cells measured by using the measuring equipment at each time point. For example, the methods of Equations 1 to 3 above may be applied.

The correction device 100 determines deviations 350 and 352 between the alternating-current resistances 340 and 342 at the nth time point and the reference alternating-current resistance 330. Specifically, the correction device 100 obtains a first deviation 350 between the first alternating-current resistance 340 measured at the second time point 312 and the reference alternating-current resistance 330, and obtains a second deviation 352 between the second alternating-current resistance 342 measured at the third time point 314 and the reference alternating-current resistance 330. In this way, the correction device 100 may obtain an (n−1)th deviation at the nth time point.

The correction device 100 may obtain deviations between the first and second alternating-current resistances 340 and 342 and the reference alternating-current resistance 330 according to the frequency of the alternating-current voltage applied to the battery sample 300. At the first time point 310, if it is assumed that the alternating-current resistance measured by applying an alternating-current voltage of a first frequency to the battery sample 300 is A1, and the alternating-current resistance measured by applying an alternating-current voltage of a second frequency to the battery sample 300 is B1. At the second time point 312, if the alternating-current resistance of the battery sample 300 measured by applying the first frequency is A2 and the alternating-current resistance of the battery sample 300 measured by applying the second frequency is B2, the correction device 100 may obtain a deviation (A1−A2) for the first frequency and a deviation (B1−B2) for the second frequency, respectively, for the second time point 312.

The correction device 100 stores the deviations 350 and 352 between the reference alternating-current resistance 330 of the first time point 310 and each of the first and second alternating-current resistances 340 and 342 of the nth time points 312 and 314. When the alternating-current resistance of an actual battery cell (not a battery sample) is measured using measuring equipment at the nth time point 312 and 314, the correction device 100 corrects the alternating-current resistance of the battery cell measured by the measuring equipment using a pre-stored (n−1)th deviation 350 and 352. For example, the correction device 100 corrects the alternating-current resistance of the first battery cell measured at the second time point 312 using the pre-stored first deviation 350, and corrects the alternating-current resistance of the second battery cell measured at the third time point 314 using the pre-stored second deviation 352.

In another embodiment, when measuring the alternating-current resistance of a battery sample using the same measuring equipment at the same time point, if the environmental conditions of the measuring equipment, such as the measuring location, change, a deviation between the alternating-current resistances may occur. For example, when measuring equipment is used at location A at the first time point 310 and when the same measuring equipment is used at location B, the alternating-current resistance measurement values of the same battery sample may be different, as shown in FIG. 2.

To correct this, the correction device 100 may identify the deviations by environmental conditions, which indicates deviations between the multiple alternating-current resistances obtained by measuring the battery sample 300 with the measuring equipment in multiple environmental conditions with different temperatures and humidity at each of the time points 310, 312, and 314 and the reference alternating-current resistance. For example, the correction device 100 may set an alternating-current resistance of the battery sample measured by using the measuring equipment at location A at the first time point 310 as the reference alternating-current resistance 330, and may obtain a deviation (hereinafter, a deviation by environmental condition) between the alternating-current resistance of the battery sample measured by the same measuring equipment at location B at the first time point 310 and the reference alternating-current resistance. The correction device 100 may correct the multiple alternating-current resistances obtained by measuring different battery cells (not battery samples) with the same measuring equipment in multiple environmental conditions at the first time point 310 using the deviation by environmental condition.

In the case of the second time point 312, if the same measuring equipment is used in different environmental conditions such as multiple measuring locations, the correction device 100 may obtain deviations by environmental condition for each environmental condition of the second time point 312. Because the second time point 312 has the first deviation from the reference alternating-current resistance of the first time point 310, the correction device 100 may correct the alternating-current resistance of the battery cell (not the battery sample) measured in multiple environmental conditions at the second time point 312 using the first deviation and the deviation by environmental condition. If the measuring equipment is used in multiple different environmental conditions at the n^{th} time point, the correction device 100, in the same way, may correct the alternating-current resistance of the battery cell measured in the n^{th} time point using the (n−1)^{th} deviation and the deviation by environmental condition.

FIG. 4 is a diagram illustrating an example of a method of correcting a deviation of measuring equipment by period according to an embodiment of the present disclosure.

Referring to FIG. 4, environmental conditions such as temperature and humidity may vary at each time the measuring equipment 400, 410, and 420 measures a battery cell. In other words, the measured values of alternating-current resistances of the same battery sample 300 measured by the measuring equipment 400, 410, and 420 may vary over time. For example, an alternating-current resistance of the battery sample 300 measured yesterday and an alternating-current resistance of the same battery sample 300 measured today may differ from each other due to environmental factors.

In the present embodiment, the time point denotes an elapsed time at which a deviation is needed to be reset, and does not necessarily mean a certain time interval. For example, a deviation setting process examined in FIG. 3 may be performed on a daily basis before using the measuring equipment 400, 410, and 420. Alternatively, the deviation setting process of FIG. 3 may be performed before using the measuring equipment 400, 410, and 420 in the morning, and the deviation setting process of FIG. 3 may be performed again before using the measuring equipment 400, 410, and 420 in the afternoon. Therefore, the time point may be modified in various ways depending on the embodiments.

The measuring equipment 400, 410, and 420 used to measure the battery cell may be in plurality. In this case, even under the same environmental conditions, the alternating-current resistance measurement values of the battery cell may be different depending on the characteristics of each measuring equipment 400, 410, and 420. For example, an alternating-current resistance of the battery sample measured by the first measuring equipment 410 and an alternating-current resistance of the battery sample measured by the second measuring equipment 420 at the first time point 310 may be different from each other. Therefore, when using multiple measuring equipment 400, 410, and 420, it is necessary to correct not only the deviation of alternating-current resistance according to the environmental conditions at each of the time points 310, 312, and 314 but also the deviation of alternating-current resistance between the measuring equipment.

Hereinafter, for the convenience of explanation, one of the multiple measuring equipment is referred to as the reference measuring equipment 400. In addition, the alternating-current resistance of the battery sample measured by the reference measuring equipment 400 at the first time point 310 is referred to as a reference alternating-current resistance.

At the first time point 310, a reference alternating-current resistance a, an alternating-current resistance 1a, and an alternating-current resistance 2a for the same battery sample 300 are measured using the reference measuring equipment 400 and the plurality of general measuring equipment 410 and 420. The correction device 100, at the first time point 310, obtains a deviation between the reference alternating-current resistance a and the alternating-current resistance 1a, and a deviation between the reference alternating-current resistance a and the alternating-current resistance 2a. Hereinafter, the deviation between the alternating-current resistances of multiple measuring equipment 400, 410, and 420 and the reference alternating-current resistance at the same time point is referred to as an equipment-specific deviation. Once the equipment-specific deviation is obtained, the correction device 100 corrects the alternating-current resistance of the battery cell (not the battery sample) measured by using the first measuring equipment 410 or the second measuring equipment 420 at the first time point 310 using the equipment-specific deviation.

The correction device 100 obtains a first deviation between the alternating-current resistance b of the battery sample measured by using the reference measuring equipment 400 at the second time point 312 and the reference alternating-current resistance a measured using the reference measuring equipment 400 at the first time point 310 using the method of FIG. 3. Also, an alternating-current resistance 1b and an alternating-current resistance 2b of the battery sample are measured using the plurality of general measuring equipment 410 and 420. The correction device 100 obtains an equipment-specific deviation between the alternating-current resistance b of the reference measuring equipment 400 and the alternating-current resistance 1b and the alternating-current resistance 2b of each of the measuring equipment 410 and 420. The correction device 100 corrects the alternating-current resistance of the battery cell measured using the first measuring equipment 410 or the second measuring equipment 420 at the second time point 312 using the equipment-specific deviation and the first deviation.

If the measuring equipment 400, 410, and 420 are to be used at the third time point 314, the correction device 100 obtains a second deviation between an alternating-current resistance c at the third time point and the reference alternating-current resistance a using the method of FIG. 3. In addition, the correction device 100 obtains the equipment-specific deviation between the alternating-current resistance c of the reference measuring equipment 400 and the alternating-current resistance 1c and the alternating-current resistance 2c of the multiple general measuring equipment 410 and 420. The correction device 100 corrects the alternating-current resistance of each battery cell measured by each of the measuring equipment 320 and 322 at the third time point 314 by using the equipment-specific deviation and the second deviation. In this way, the correction device 100 may obtain the (n−1)^{th} deviation and the equipment-specific deviation at the n^{th} time point and use them to correct the deviation of alternating-current resistance.

The correction method described above may be expressed in Equation 4 as follows.

$${EIS}_{calibration} ( f ) = {EIS}_{raw} ( f ) + {δ}_{ref - j , device} ( f ) + {δ}_{ref - i , day} ( f ) \qquad [ Equation 4 ]$$

$${δ}_{ref - j , device} = \text{?} ( f ) - \text{?} ( f )$$

$${δ}_{ref - i , day} = \text{?} ( f ) - \text{?} ( f )$$

Here, EIS_{calibration}(f) is a corrected value of an alternating-current resistance measured by applying an alternating-current voltage of frequency f to the battery cell (not the battery sample), EIS_{raw}(f) is an alternating-current resistance measured by applying an alternating-current voltage of frequency f to the battery cell using measuring equipment 320 and 322, δ_{ref-j.device}(f) is the equipment-specific deviation, and δ_{ref-i.day}(f) represents the n^{th} deviation between time points. EIS_{ref device@ith day}(f) represents the alternating-current resistance of the battery sample 300 measured by the reference measuring equipment 400 at the ith time point, and EIS_{jth device@ith day}(f) represents the alternating-current resistance of the battery sample measured by the general measuring equipment 410 and 420 at the ith time point. In addition, EIS_{ref device@ref day}(f) refers to the reference alternating-current resistance of the battery sample measured by the reference measuring equipment 400 at the first time point, and EIS_{ref device@ith day}(f) refers to an alternating-current resistance of the battery sample measured by the reference measuring equipment 400 at the ith time point.

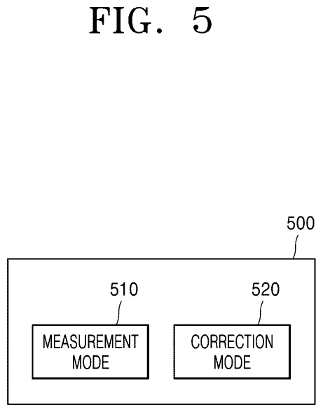

FIG. 5 is a diagram illustrating an example of a user interface 500 for correcting a deviation of battery measurement information according to an embodiment of the present disclosure. The present embodiment presents an example of the user interface 500 for the method of correcting a deviation of FIG. 4.

Referring to FIG. 5, the correction device 100 provides the user interface 500 that may select a measurement mode 510 or a correction mode 520. When the user selects the correction mode 520, the correction device 100 receives an alternating-current resistance measurement value of a battery sample from the reference measuring equipment 400 (see FIG. 4) and the at least one general measuring equipment 410 and 420 (see FIG. 4), respectively.

In an embodiment, the reference measuring equipment 400 and the at least one measuring equipment 410 and 420 are connected to the correction device 100 by wire or wirelessly, and may transmit the measurement value together with their own identification information to the correction device 100. In this case, the correction device 100 may recognize and store the measurement value by using the identification information.

As another embodiment, the correction device 100 may provide a user interface through which the user may select the reference measuring equipment or the general measuring equipment. The user may select the reference measuring equipment or the general measuring equipment through the user interface and may input an alternating-current resistance of the battery sample measured by the reference measuring equipment or general measuring equipment to the correction device 100 through the user interface. Alternatively, the reference measuring equipment or the general measuring equipment may be connected to the correction device 100 by wire or wirelessly, and the user only needs to select the reference measuring equipment or the general measuring equipment through the user interface, and the alternating-current resistance measurement value measured by the reference measuring equipment or the general measuring equipment may be automatically transmitted to the correction device 100.

The correction device 100 identifies and stores a deviation between the reference alternating-current resistance received from the reference measuring equipment and the alternating-current resistance received from the general measuring equipment. The correction device 100 may identify and store the deviation by environmental conditions, as in the embodiment of FIG. 3.

When the user selects the measurement mode 510, the correction device 100 corrects the alternating-current resistance of the battery cell measured by the general measuring equipment using a deviation identified in the previous correction mode 520.

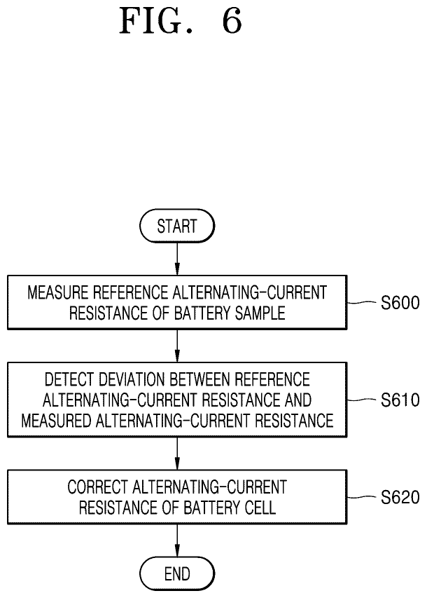

FIG. 6 is a flowchart illustrating an example of a battery measurement information correction method according to an embodiment of the present disclosure.

Referring to FIG. 6, when the correction device 100 receives an alternating-current resistance measurement value of a battery sample from a measuring equipment at the first time point, the correction device 100 stores the alternating-current resistance measurement value as a reference alternating-current resistance (S600). When the correction device 100 receives an alternating-current resistance measurement value of the battery sample from the measuring equipment at an n^{th} time point, the correction device 100 determines and stores a deviation between the reference alternating-current resistance and the alternating-current resistance of the battery sample measured by the measuring equipment at the n^{th} time point (S610). In another embodiment, the correction device 100 may identify and store the equipment-specific deviations as examined in FIG. 4. Also, in another embodiment, the correction device 100 may identify and store deviations by environmental conditions as examined in FIG. 3.

The correction device 100 corrects the alternating-current resistance of a battery cell (a battery cell different from the battery sample) measured using a measuring equipment at the n^{th} time point using the deviation (S620). In another embodiment, if the equipment-specific deviation are identified together with an (n−1)^{th} deviation, the correction device 100 corrects the alternating-current resistance using the (n−1)^{th} deviation and the equipment-specific deviation together.

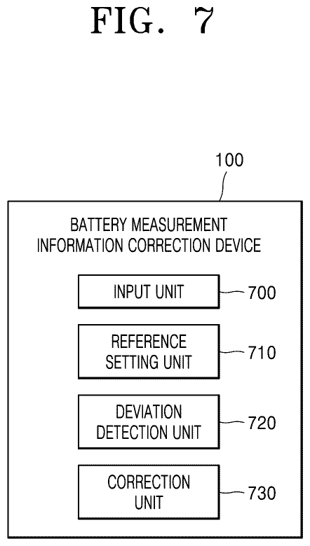

FIG. 7 is a diagram illustrating an example of a configuration of a battery measurement information correction device according to an embodiment of the present disclosure.

Referring to FIG. 7, the correction device 100 includes an input unit 700, a reference setting unit 710, a deviation detection unit 720, and a correction unit 730. According to an embodiment, the input unit 700 may be omitted. In an embodiment, the correction device 100 may be implemented as a computing device including a memory, a processor, and an input/output device. In this case, each configuration may be implemented as software and loaded onto the memory and then executed by the processor.

The reference setting unit 710 sets an alternating-current resistance of a battery sample measured by measuring equipment at a first time point as a reference alternating-current resistance.

The deviation detection unit 720 determines a first deviation between the alternating-current resistance measured by the same measuring equipment at a second time point and the reference alternating-current resistance. In addition, the deviation detection unit 720 detects a second deviation between the alternating-current resistance measured by the same measuring equipment at a third time point and the reference alternating-current resistance. In this way, the deviation detection unit 720 may obtain an (n−1)^{th} deviation at an n^{th} time point.

The correction unit 730 corrects the alternating-current resistance of the battery cell (not the battery sample) measured by the measuring equipment at the second time point by using the first deviation. In addition, the correction unit 730 corrects the alternating-current resistance of the battery cell measured by the measuring device at the third time point by using the second deviation. In this way, the correction unit 730 corrects the alternating-current resistance of the battery cell measured by the measuring device at the n^{th} time point by using the (n−1)^{th} deviation.

In another embodiment, the deviation detection unit 720 may detect the deviation by environmental condition, which represents a deviation between the reference alternating-current resistance and the plurality of alternating-current resistances obtained by measuring the battery sample with the same measuring equipment under multiple environmental conditions with different temperatures and humidity at the second time point. In this case, the correction unit 730 may additionally correct the alternating-current resistances of different battery cells measured by the measuring equipment under multiple environmental conditions using the deviations by environmental conditions.

In another embodiment, the deviation detection unit 720 may detect the equipment-specific deviations indicating the respective deviations between the multiple alternating-current resistances obtained by measuring battery samples with multiple measuring equipment at the second time point and the reference alternating-current resistance. In this case, the correction unit 730 may correct the multiple alternating-current resistances obtained by measuring different battery cells with multiple measuring equipment at the second time point using the equipment-specific deviations.

The input unit 700 provides a user interface that may select a measurement mode or a correction mode. When the correction mode 520 is selected, the deviation detection unit 720 detects and stores the (n−1)^{th} deviation by time point, and when the correction mode 510 is selected, the correction unit 730 corrects the alternating-current resistance of the battery cell measured by the measuring equipment using the previously detected (n−1)^{th} deviation. In another embodiment, if the deviation detection unit 720 detects and stores the deviation by environmental conditions or by equipment-specific deviation, the correction unit 730 may correct the alternating-current resistance of the battery cell by using the deviation by environmental conditions or equipment-specific deviation together with the (n−1)^{th} deviation.

The present disclosure may also be implemented as a non-transitory computer-readable program code on a computer-readable recording medium. The non-transitory computer-readable recording medium includes all types of recording devices that store data that may be read by a computer system. Examples of the non-transitory computer-readable recording medium include read-only memory (ROM), random access memory (RAM), CD-ROM, magnetic tape, floppy disk, optical data storage device, etc. In addition, the non-transitory computer-readable recording medium may be distributed to computer systems connected to a network, and the computer-readable code may be stored and executed in a distributed manner.

The present disclosure has been particularly shown and described with reference to embodiments thereof. It will be understood by those of ordinary skill in the art that various changes in form and details may be made therein without departing from the spirit and scope of the present disclosure as defined by the appended claims. Therefore, the embodiments should be considered in descriptive sense only and not for purposes of limitation. The scope of the present disclosure is defined not by the detailed description above but by the appended claims, and all differences within the scope will be construed as being included in the present disclosure.

1. A method of correcting battery measurement information, the method comprising:
setting an alternating-current resistance of a battery sample measured by using measuring equipment at a first time point as a reference alternating-current resistance;
determining a first deviation between an alternating-current resistance obtained by measuring the battery sample by using the measuring equipment at a second time point and the reference alternating-current resistance; and
correcting an alternating-current resistance of a battery cell measured by the measuring equipment at the second time point by using the first deviation.

2. The method of claim 1, further comprising:
determining a second deviation between an alternating-current resistance obtained by measuring the battery sample by using the measuring equipment at a third time point and the reference alternating-current resistance; and
correcting an alternating-current resistance of the battery cell measured by the measuring equipment at the third time point by using the second deviation.

3. The method of claim 1, further comprising:
identifying deviations by environmental condition, which represent deviations between a plurality of alternating-current resistances obtained by measuring the battery sample with the measuring equipment under a plurality of environmental conditions with different temperatures and humidity at the second time point and the reference alternating-current resistance, respectively; and
correcting a plurality of alternating-current resistances obtained by measuring different battery cells with the measuring equipment under the plurality of environmental conditions by using the deviations by environmental condition, respectively.

4. The method of claim 1, further comprising:
identifying equipment-specific deviations representing deviations between a plurality of alternating-current resistances obtained by measuring the battery sample with a plurality of measuring equipment at the second time point and the reference alternating-current resistance, respectively; and
correcting a plurality of alternating-current resistances obtained by measuring different battery cells with the plurality of measuring equipment at the second time point by using the equipment-specific deviations, respectively.

5. The method of claim 1, further comprising providing a user interface for selecting a measurement mode or a correction mode,
wherein, when the correction mode is selected, the first deviation is identified and stored, and
when the measurement mode is selected, the alternating-current resistance of the battery cell measured by the measuring equipment is corrected using the first deviation previously identified.

6. A battery measurement information correction device comprising:
a reference setting unit that sets an alternating-current resistance of a battery sample measured by measuring equipment at a first time point as a reference alternating-current resistance;
a deviation detection unit that detects a first deviation between an alternating-current resistance obtained by measuring the battery sample by using the measuring equipment at a second time point and the reference alternating-current resistance; and
a correction unit that corrects an alternating-current resistance of a battery cell measured by the measuring equipment at the second time point by using the first deviation.

7. The battery measurement information correction device of claim 6, wherein
the deviation detection unit detects a second deviation between an alternating-current resistance obtained by measuring the battery sample by using the measuring equipment at a third time point, and
the correction unit corrects an alternating-current resistance of the battery cell measured by using the measuring equipment at the third time point by using the second deviation.

8. The battery measurement information correction device of claim 6, wherein
the deviation detection unit detects deviations by environmental condition, which represent deviations between a plurality of alternating-current resistances obtained by measuring the battery sample with the measuring equipment under a plurality of environmental conditions of different temperatures and humidity at the second time point, and the reference alternating-current resistance, respectively, and
the correction unit corrects a plurality of alternating-current resistances obtained by measuring different battery cells with the measuring equipment under the plurality of environmental conditions by using the deviations by environmental condition, respectively.

9. The battery measurement information correction device of claim 6, wherein
the deviation detection unit detects equipment-specific deviations representing deviations between a plurality of alternating-current resistances obtained by measuring the battery sample with a plurality of measuring equipment at the second time point and the reference alternating-current resistance, respectively, and
the correction unit corrects a plurality of alternating-current resistances obtained by measuring different battery cells with the plurality of measuring equipment at the second time point by using the equipment-specific deviations, respectively.

10. The battery measurement information correction device of claim 6, further comprising
an input unit providing a user interface for selecting a measurement mode or a correction mode,
wherein, when the correction mode is selected, the first deviation is identified and stored, and
when the measurement mode is selected, the alternating-current resistance of the battery cell measured by the measuring equipment is corrected using the first deviation previously identified.

11. A non-transitory computer-readable recording medium having recorded thereon a computer program for performing the method of claim 1.
